(19) United States
(12) Patent Application Publication
(10) Pub. No.: US 2025/0344570 A1
(43) Pub. Date: Nov. 6, 2025

(54) STACKED OLED DEVICE AND DISPLAY PANEL

(71) Applicant: BOE TECHNOLOGY GROUP CO., LTD., Beijing (CN)

(72) Inventors: Yongqi SHEN, Beijing (CN); Juanjuan YOU, Beijing (CN); Cheng XU, Beijing (CN); Dandan ZHOU, Beijing (CN); Wei QUAN, Beijing (CN)

(21) Appl. No.: 18/861,534

(22) PCT Filed: Nov. 23, 2022
(86) PCT No.: PCT/CN2022/133818

§ 371 Date: Oct. 29, 2024

(51) Int. Cl. H10K 50/13; H10K 101/30; H10K 101/40; H10K 102/00

(52) U.S. Cl. CPC H10K 50/131; H10K 2101/30; H10K 2101/40; H10K 2102/351

(57) ABSTRACT

An OLED device includes a driving backplane and a plurality of sub-pixels distributed in an array on the driving backplane, where the sub-pixel includes a first light-emitting unit located at a side of the driving backplane, and a second light-emitting unit located at a side of the first light-emitting unit away from the driving backplane. The second light-emitting unit includes a first light-emitting sub-layer, a second light-emitting sub-layer located at a side of the first light-emitting sub-layer away from the driving backplane, and a first function adjusting layer that is located between the first light-emitting sub-layer and the second light-emitting sub-layer or located at a side of the second light-emitting sub-layer away from the first light-emitting sub-layer. The first function adjusting layer is configured to balance a transport difference of carriers in the second light-emitting unit.

### TECHNICAL FIELD

The present disclosure relates to the field of display technologies, and specifically to a stacked OLED device and a display panel.

### BACKGROUND

A tandem organic light-emitting diode (OLED) device is a kind of stacked OLED device formed by electrically connecting a plurality of organic light-emitting (EL) units in series in the device. The tandem OLED device has both high efficiency and long lifetime characteristics.

In the related art, there may be color deviation problems with the tandem OLED device during use.

It should be noted that the information disclosed in the background section above is only used for enhancing the understanding of the background of the present disclosure, and therefore may include information that does not constitute prior art known to those ordinary skilled in the art.

### SUMMARY

An object of the present disclosure is to overcome the deficiencies of the prior art described above, and provide a stacked OLED device and a display panel.

According to an aspect of the present disclosure, there is provided a stacked OLED device that includes a driving backplane and a plurality of sub-pixels distributed in an array on the driving backplane. The sub-pixel includes: a first light-emitting unit, located at a side of the driving backplane; and a second light-emitting unit, located at a side of the first light-emitting unit away from the driving backplane. The second light-emitting unit includes: a first light-emitting sub-layer; a second light-emitting sub-layer, located at a side of the first light-emitting sub-layer away from the driving backplane, where the second light-emitting sub-layer is provided with a luminescence color different from a luminescence color of the first light-emitting sub-layer; and a first function adjusting layer, located between the first light-emitting sub-layer and the second light-emitting sub-layer, or located at a side of the second light-emitting sub-layer away from the first light-emitting sub-layer. The first function adjusting layer is configured to balance a transport difference of carriers in the second light-emitting unit.

In an exemplary embodiment of the present disclosure, the sub-pixel further includes a third light-emitting unit that is located at a side of the second light-emitting unit away from the driving backplane, where the third light-emitting unit is provided with a same luminescence color as the first light-emitting unit.

In an exemplary embodiment of the present disclosure, the first light-emitting sub-layer is provided with less luminescence energy than the second light-emitting sub-layer.

In an exemplary embodiment of the present disclosure, the first light-emitting sub-layer is an R light-emitting layer, and the second light-emitting sub-layer is a Y light-emitting layer.

In an exemplary embodiment of the present disclosure, the first function adjusting layer includes a first adjusting layer, where the first adjusting layer is located at the side of the second light-emitting sub-layer away from the driving backplane; and the first adjusting layer is a light-emitting layer, and the first adjusting layer is provided with the same luminescence color as the first light-emitting sub-layer.

In an exemplary embodiment of the present disclosure, the second light-emitting unit further includes an electron transport layer that is located at the side of the second light-emitting sub-layer away from the first light-emitting sub-layer; where a host material in the first adjusting layer is provided with a greater electron mobility than a host material in the first light-emitting sub-layer.

In an exemplary embodiment of the present disclosure, the second light-emitting unit further includes a hole transport layer that is located between the first light-emitting sub-layer and the first light-emitting unit; where a host material in the first adjusting layer is provided with a deeper HOMO energy level than a host material in the first light-emitting sub-layer, and a host material in the second light-emitting sub-layer.

In an exemplary embodiment of the present disclosure, the host material in the first adjusting layer is provided with a smaller hole mobility than the host material in the first light-emitting sub-layer.

In an exemplary embodiment of the present disclosure, the first function adjusting layer includes a second adjusting layer, where the second adjusting layer is a non-light-emitting layer, and the second adjusting layer is located between the first light-emitting sub-layer and the second light-emitting sub-layer.

In an exemplary embodiment of the present disclosure, the second light-emitting unit further includes a hole transport layer that is located between the first light-emitting sub-layer and the first light-emitting unit; where a hole mobility of the second adjusting layer is greater than a hole mobility of a host material in the first light-emitting sub-layer, and a hole mobility of a host material in the second light-emitting sub-layer.

In an exemplary embodiment of the present disclosure, a ratio of the hole mobility of the second adjusting layer to the hole mobility of the host material in the second light-emitting sub-layer is greater than or equal to 1.5.

In an exemplary embodiment of the present disclosure, the second light-emitting unit further includes an electron transport layer that is located at the side of the second light-emitting sub-layer away from the first light-emitting sub-layer; where an electron mobility of the second adjusting layer is matched with an electron mobility of the electron transport layer.

In an exemplary embodiment of the present disclosure, in a thickness direction of the driving backplane, a thickness of the second adjusting layer is less than a thickness of the first light-emitting sub-layer, and a thickness of the second light-emitting sub-layer.

In an exemplary embodiment of the present disclosure, a ratio of the thickness of the second adjusting layer to the thickness of the first light-emitting sub-layer is greater than or equal to 1/15, and less than or equal to 3/5.

In an exemplary embodiment of the present disclosure, the thickness of the second adjusting layer is 1 to 3 nm.

In an exemplary embodiment of the present disclosure, the sub-pixel further includes: a first charge generating layer, located between the first light-emitting unit and the second light-emitting unit, where the first charge generating layer is configured to provide an electron to the first light-emitting unit and provide a hole to the second light-emitting unit; a second charge generating layer, located between the second light-emitting unit and the third light-emitting unit, where the second charge generating layer is configured to provide an electron to the second light-emitting unit and provided a hole to the third light-emitting unit; and a second function adjusting layer, located between the second light-emitting sub-layer and the second charge generating layer; where the second charge generating layer is doped with an active metal element, and the second function adjusting layer is configured to block diffusion of the active metal element doped in the second charge generating layer.

In an exemplary embodiment of the present disclosure, the second light-emitting unit further includes an electron transport layer that is located between the second function adjusting layer and the second charge generating layer; where a LUMO energy level of the second function adjusting layer is between a LUMO energy level of the electron transport layer and a LUMO energy level of the second charge generating layer.

In an exemplary embodiment of the present disclosure, the LUMO energy level of the second function adjusting layer is greater than or equal to 3 eV.

In an exemplary embodiment of the present disclosure, the second function adjusting layer is provided with a greater electron mobility than the electron transport layer.

In an exemplary embodiment of the present disclosure, in a thickness direction of the driving backplane, a thickness of the second function adjusting layer is less than or equal to a thickness of the second light-emitting sub-layer.

In an exemplary embodiment of the present disclosure, a ratio of the thickness of the second function adjusting layer to a thickness of the first light-emitting sub-layer is greater than or equal to 2/3, and less than or equal to 4; and a ratio of the thickness of the second function adjusting layer to the thickness of the second light-emitting sub-layer is greater than or equal to 1/4, and less than or equal to 4/5.

According to a second aspect of the present disclosure, there is also provided a display panel that includes the OLED device according to any embodiment of the present disclosure.

The stacked OLED device in the present disclosure is provided with the first function adjusting layer in the second light-emitting unit, and the transport difference of carriers in the second light-emitting unit can be adjusted by the first function adjusting layer. Therefore, during the use of the device, the luminescence ratio between the first light-emitting sub-layer and the second light-emitting sub-layer is kept stable, which makes the luminescence color ratio of the stacked OLED device maintain stable, and reduces the color difference of the device at different brightness and different operating stages.

It should be understood that the above general description and the subsequent detailed description are merely exemplary and explanatory, and do not limit the present disclosure.

### BRIEF DESCRIPTION OF THE DRAWINGS

The accompanying drawings herein, which are incorporated into and form a part of the specification, illustrate embodiments consistent with the present disclosure and are used in conjunction with the specification to explain the principles of the present disclosure. It will be apparent that the accompanying drawings in the following description are only some of the embodiments of the present disclosure, and that other accompanying drawings can be obtained based on these accompanying drawings without creative labor for those ordinary skilled in the art.

FIG. 1 is a schematic structural diagram of a stacked OLED device according to an embodiment of the present disclosure;

FIG. 2 is a schematic structural diagram of a stacked OLED device according to another embodiment of the present disclosure;

FIG. 3 is a schematic structural diagram of a stacked OLED device according to another embodiment of the present disclosure;

FIG. 4 is a schematic structural diagram of a stacked OLED device according to yet another embodiment of the present disclosure;

FIG. 5 is a schematic structural diagram of a sub-pixel according to an embodiment of the present disclosure;

FIG. 6 is a schematic structural diagram of a second light-emitting unit according to an embodiment of the present disclosure;

FIG. 7 is a schematic structural diagram of a second light-emitting unit according to another embodiment of the present disclosure;

FIG. 8 is a schematic structural diagram of a second light-emitting unit according to yet another embodiment of the present disclosure.

### DETAILED DESCRIPTION

Exemplary embodiments are now described more comprehensively with reference to the accompanying drawings. However, the exemplary embodiments are capable of being implemented in a variety of forms, and should not be construed as being limited to the embodiments set forth herein. Rather, the provision of these embodiments allows for the present disclosure to be comprehensive and complete, and conveys the idea of the exemplary embodiments in a comprehensive manner to those skilled in the art. The same reference numerals in the drawings indicate the same or similar structures, and therefore their detailed descriptions will be omitted. In addition, the accompanying drawings are only schematic illustrations of the present disclosure, and are not necessarily drawn to scale.

In the related art, a conventional stacked OLED device mainly forms a B-YR structure by stacking two layers of light-emitting units, or a B-YR-B structure by stacking three layers of light-emitting units. Generally, an R organic light-emitting layer and a Y organic light-emitting layer are placed in one light-emitting unit, and then combined with one or two B light-emitting units to form an OLED system with light output close to the normal white point, thereby improving the light output effect. However, the inventor found that this stacked OLED device has the following problems: the first one is that the light output ratio of R/Y changes with the change of light intensity; the second one is that as the device operates, the overall carrier balance of the device changes, and the deviation in the light output of R/Y occurs.

To this end, the inventor provides a novel stacked OLED device to solve the above problems.

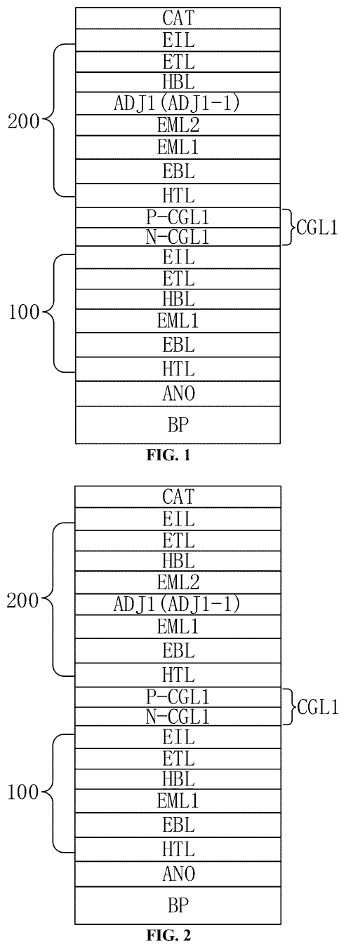

FIG. 1 is a schematic structural diagram of a stacked OLED device according to an embodiment of the present disclosure, and FIG. 2 is a schematic structural diagram of a stacked OLED device according to another embodiment of the present disclosure. As shown in FIGS. 1 and 2, the stacked OLED device may include a driving backplane BP and a plurality of sub-pixels distributed in an array on the driving backplane. The sub-pixels may, for example, include R sub-pixels and/or G sub-pixels and/or B sub-pixels. The sub-pixel may include a first light-emitting unit 100 and a second light-emitting unit 200. The first light-emitting unit 100 is located at a side of the driving backplane BP, and the second light-emitting unit 200 is located at a side of the first light-emitting unit 100 away from the driving backplane BP, i.e., the first light-emitting unit 100 and the second light-emitting unit 200 are stacked at a side of the driving backplane BP. The second light-emitting unit 200 may include a first light-emitting sub-layer EML1, a second light-emitting sub-layer EML2 and a first function adjusting layer ADJ1, where the second light-emitting sub-layer EML2 is located at a side of the first light-emitting sub-layer EML1 away from the driving backplane BP, the second light-emitting sub-layer EML2 is provided with a luminescence color different from a luminescence color of the first light-emitting sub-layer EML1; the first function adjusting layer ADJ1 is located between the first light-emitting sub-layer EML1 and the second light-emitting sub-layer EML2, or located at a side of the second light-emitting sub-layer EML2 away from the first light-emitting sub-layer EML1; and the first function adjusting layer ADJ1 is configured to balance a transport difference of carriers in the second light-emitting unit 200.

The stacked OLED device in the present disclosure is provided with the first function adjusting layer ADJ1 in the second light-emitting unit 200, and the transport difference of carriers in the second light-emitting unit 200 can be adjusted by the first function adjusting layer ADJ1. Therefore, during the use of the device, the luminescence ratio between the first light-emitting sub-layer EML1 and the second light-emitting sub-layer EML2 is kept stable, which makes the luminescence color ratio of the stacked OLED device maintain stable, and reduces the color difference of the device at different brightness and different operating stages.

The first light-emitting unit 100 and the second light-emitting unit 200 in the present disclosure are stacked at a side of the driving backplane BP to form the stacked OLED device. In some embodiments, the first light-emitting unit 100 may include a single light-emitting layer, and the second light-emitting unit 200 may include a plurality of light-emitting layers. For example, the first light-emitting unit 100 may include an organic light-emitting layer EML-B, i.e., the first light-emitting unit 100 emits blue light. The second light-emitting unit 200 may include a first light-emitting sub-layer EML1 and a second light-emitting sub-layer EML2. The first light-emitting sub-layer EML1 may be an organic light-emitting layer EML-R that emits red light, and the second light-emitting sub-layer EML2 may be an organic light-emitting layer EML-Y that emits yellow light, thereby forming a B-RY stacked OLED light-emitting device. When the first light-emitting unit 100 and the second light-emitting unit 200 emit light simultaneously, the sub-pixel is enabled to emit white light, and then the sub-pixel emits light of the corresponding color through the action of the color film layer. Of course, in other embodiments, the first light-emitting unit 100 and the second light-emitting unit 200 may also have other light-emitting layer structures, which will not be described in detail here.

The first function adjusting layer ADJ1 may be located between the first light-emitting sub-layer EML1 and the second light-emitting sub-layer EML2, or may be located at the side of the second light-emitting sub-layer EML2 away from the first light-emitting sub-layer EML1. The first function adjusting layer ADJ1 can balance the transport difference of carriers in the second light-emitting unit 200. Specifically, carriers may include holes and electrons. During different using stages of the stacked OLED or when the voltage applied to two ends of the stacked OLED changes, the transport characteristic of electrons and the transport characteristic of holes may change, disrupting the transport balance between electrons and holes. For example, the transport rate of electrons and the transport rate of holes may change during the use of the device, causing the exciton recombination region in the second light-emitting unit 200 to shift, which results in a change in the ratio of the energy obtained by the first light-emitting sub-layer EML1 to the energy obtained by the second light-emitting sub-layer EML2 in the second light-emitting unit 200, and therefore causes a change in the luminescence ratio of the first light-emitting sub-layer EML1 to the second light-emitting sub-layer EML2. The present disclosure provides the first function adjusting layer ADJ1 in the second light-emitting unit 200, and the first function adjusting layer can balance the transport difference of carriers in the second light-emitting unit 200. That is, during different using stages of the stacked OLED device or when the voltage applied to two ends of the stacked OLED device changes, the first function adjusting layer can maintain a balanced relationship between electrons and holes in the second light-emitting unit 200, for example, the first function adjusting layer controls the recombination ratio of electrons and holes to maintain stable, and thus controls the luminescence color of the second light-emitting unit 200 to be stable, thereby making the luminescence color of the stacked OLED device stable.

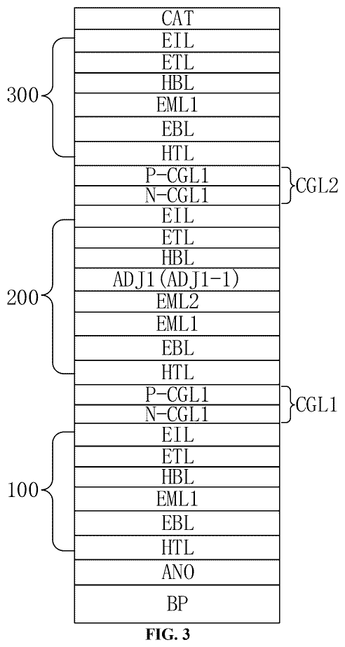

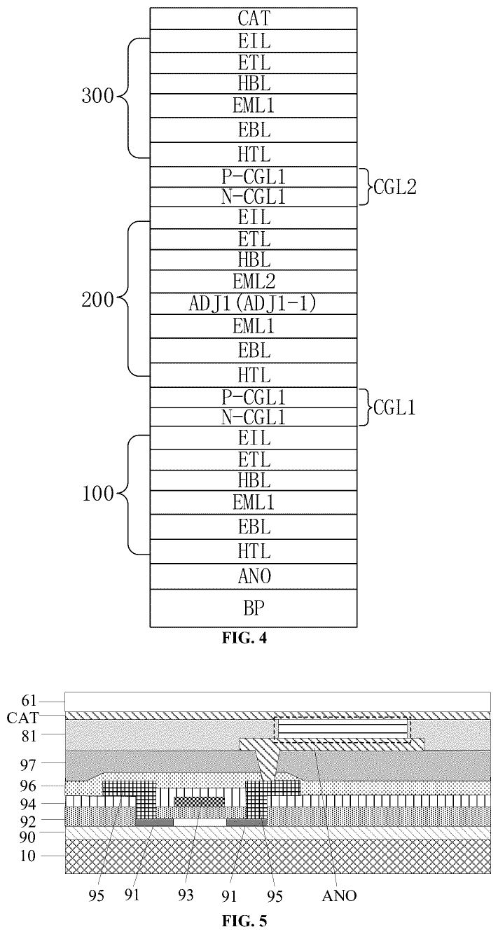

FIG. 3 is a schematic structural diagram of a stacked OLED device according to another embodiment of the present disclosure, and FIG. 4 is a schematic structural diagram of a stacked OLED device according to yet another embodiment of the present disclosure. As shown in FIGS. 3 and 4, the difference from the devices shown in FIGS. 1 and 2 above is that the stacked OLED device may further include a third light-emitting unit 300. The first light-emitting unit 100, the second light-emitting unit 200 and the third light-emitting unit 300 are sequentially stacked at a side of the driving backplane BP, and the third light-emitting unit 300 may be provided with a same luminescence color as the first light-emitting unit 100, that is, the third light-emitting unit 300 may include an organic light-emitting layer EML-B that emits blue light. Therefore, the first light-emitting unit 100, the second light-emitting unit 200 and the third light-emitting unit 300 are connected in series to form a B-RY-B stacked OLED device structure. It should be understood that in the stacked OLED devices shown in FIGS. 3 and 4, the structure of the first light-emitting unit 100 and the structure of the second light-emitting unit 200 may be same as the structure of the first light-emitting unit 100 and the structure of the second light-emitting unit 200 in the stacked OLED devices shown in FIGS. 1 and 2 correspondingly, that is, the first function adjusting layer ADJ1 may also be provided in the second light-emitting unit 200, and the first function adjusting layer ADJ1 can achieve the same technical effect.

In some embodiments of the present disclosure, as shown in FIGS. 1 and 2, when the stacked OLED device includes two light-emitting units, the stacked OLED device may further include an anode ANO, a first charge generating layer CGL1 and a cathode CAT. The anode ANO, the first light-emitting unit 100, the first charge generating layer CGL1, the second light-emitting unit, and the cathode CAT are sequentially stacked at a side of the driving backplane BP. At this time, the stacked OLED device may further include a first charge generating layer CGL1, where the first charge generating layer CGL1 is located between the first light-emitting unit 100 and the second light-emitting unit 200, thereby connecting the first light-emitting unit 100 and the second light-emitting unit 200 in series. The first charge generating layer CGL1 may include an N-type charge generating layer N-CGL1 and a P-type charge generating layer P-CGL1 that are stacked in a thickness direction of the driving backplane BP, and configured for balancing the transport of carriers. The first charge generating layer CGL1 is generally composed of an organic material with a high carrier transport rate doped with an active metal (generally Li). Under the action of an electric field, the CGL layer undergoes charge separation, with electrons transporting to the electron transport layer ETL and holes transporting to the hole transport layer HTL.

In other embodiments of the present disclosure, as shown in FIGS. 3 and 4, when the stacked OLED device includes three light-emitting units, the stacked OLED device may further include an anode ANO, a first charge generating layer CGL1, a second charge generating layer CGL2, and a cathode CAT. The anode ANO, the first light-emitting unit 100, the first charge generating layer CGL1, the second light-emitting unit 200, the second charge generating layer CGL2, the third light-emitting unit 300, and the cathode CAT are sequentially stacked at a side of the driving backplane BP. The first light-emitting unit 100 and the second light-emitting unit 200 are connected in series through the first charge generating layer CGL1, and the second light-emitting unit 200 and the third light-emitting unit 300 are connected in series through the second charge generating layer CGL2. Similar to the first charge generating layer CGL1, the second charge generating layer CGL2 is composed of an organic material with a high carrier transport rate doped with an active metal (generally Li). Under the action of an electric field, the CGL layer undergoes charge separation, with electrons transporting to the electron transport layer ETL and holes transporting to the hole transport layer HTL.

As shown in FIGS. 3 and 4, in an exemplary embodiment, the first light-emitting unit 100, the second light-emitting unit 200 and the third light-emitting unit 300 may each include at least a part of the following film layers: a hole transport layer HTL, an electron blocking layer EBL, a hole blocking layer HBL, an electron transport layer ETL, and an electron injection layer EIL. Taking the example that each of the first light-emitting unit 100, the second light-emitting unit 200 and the third light-emitting unit 300 includes all of the above-described film layers, in the first light-emitting unit 100, the hole transport layer HTL, the electron blocking layer EBL, the first light-emitting layer EML-B, the hole blocking layer HBL, the electron transport layer ETL, and the electron injection layer EIL are sequentially stacked at a side of the anode ANO. In the second light-emitting unit 200, the hole transport layer HTL, the electron blocking layer EBL, the first light-emitting sub-layer EML1, the second light-emitting sub-layer EML2, the hole blocking layer HBL, the electron transport layer ETL, and the electron injection layer EIL are sequentially stacked at a side of the first charge generating layer CGL1. In the third light-emitting unit 300, the hole transport layer HTL, the electron blocking layer EBL, the first light-emitting layer EML-B, the hole blocking layer HBL, the electron transport layer ETL, and the electron injection layer EIL are sequentially stacked at a side of the second charge generating layer CGL2.

FIG. 5 is a schematic structural diagram of a sub-pixel according to an embodiment of the present disclosure. As shown in FIG. 5, the position of the dashed box in the drawing corresponds to the sub-pixel shown in any of FIGS. 1 to 4. The driving backplane BP may be configured to form a driving circuit for driving the OLED device to emit light. The driving circuit may include, for example, a pixel driving circuit, and the pixel driving circuit includes a driving transistor. The driving backplane BP includes a substrate 10 and a driving transistor located at a side of the substrate 10. For example, the driving transistor may include a buffer layer 90, an active layer 91, a gate insulating layer 92, a gate layer 93, an interlayer insulating layer 94, a source drain layer 95, a passivation layer 96, and a planarization layer 97, etc. The above-described film layers may be sequentially produced from bottom to top, and form corresponding patterns through patterning processes. It should be noted that the structure of the driving transistor is not limited to this, and can be determined according to actual needs. The driving circuit and various leads are provided at the position of the driving backplane BP corresponding to the peripheral area. The leads and other components in the peripheral area may be formed by using the same material as the source drain layer or gate layer of the display area through the synchronous patterning process, thereby simplifying the preparation method.

In addition, as shown in FIG. 5, a pixel defining layer 81 provided with an opening is formed at a side of the driving backplane BP. The opening of the pixel defining layer 81 exposes the anode ANO, and the anode ANO is connected to the drain of the driving transistor through a via. Then, the light-emitting structure of the sub-pixel shown in any of FIGS. 1 to 4 and the cathode CAT covering the light-emitting structure are formed in the opening area. A well-formed light-emitting device can emit light under the drive of the driving transistor. Moreover, it can be understood that there may be other film layer structures such as an encapsulation layer 61 at a side of the cathode CAT away from the substrate, which will not be described in detail here.

Taking the B-RY stacked light-emitting device structure shown in FIG. 1 and the B-RY-B stacked light-emitting device shown in FIG. 4 as examples, the structure and adjusting principle of the first function adjusting layer ADJ1 of the present disclosure are specifically introduced.

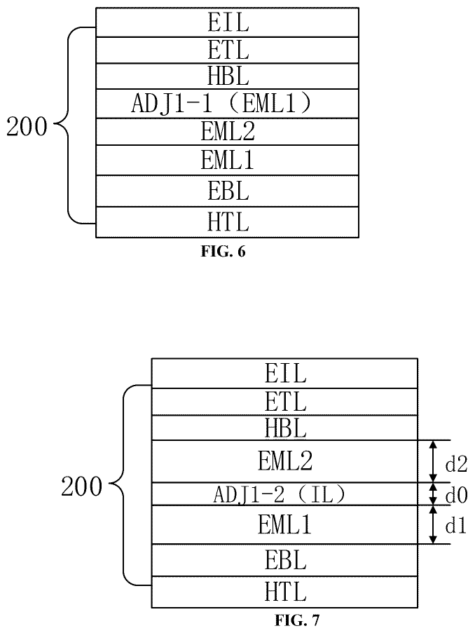

FIG. 6 is a schematic structural diagram of a second light-emitting unit according to an embodiment of the present disclosure. As shown in FIG. 6, in an exemplary embodiment, the first function adjusting layer ADJ1 includes a first adjusting layer ADJ1-1, and the first adjusting layer ADJ1-1 is located on the side of the second light-emitting sub-layer EML2 away from the driving backplane BP. In some embodiments, the first adjusting layer ADJ1-1 is a light-emitting layer, and the first adjusting layer ADJ1-1 is provided with the same luminescence color as the first light-emitting sub-layer EML1, that is, the first adjusting layer ADJ1-1 is an EML-R light-emitting sub-layer that emits red light. Because both the first light-emitting sub-layer EML1 and the first adjusting layer ADJ1-1 emit red light, the total luminescence color ratio of R-Y in the second light-emitting unit 200 is (R1+R2)/Y, where R1 represents the luminescence amount of the first light-emitting sub-layer EML1, R2 represents the luminescence amount of the first adjusting layer ADJ1-1, and Y represents the luminescence amount of the second light-emitting sub-layer EML2. In the initial using stage of the device, the exciton recombination region is close to the area between the first light-emitting sub-layer EML1 and the second light-emitting sub-layer EML2, resulting in a large luminescence ratio between the first light-emitting sub-layer EML1 and the second light-emitting sub-layer EML2, i.e., R1/Y is large, while the luminescence ratio between the second light-emitting sub-layer EML2 and the first adjusting layer ADJ1-1 is small, i.e., R2/Y is small. As the device continues to be used, the carrier balance changes and the transport rate of electrons slows down, causing the exciton recombination region formed by electrons and holes to shift towards the first function adjusting layer ADJ1. That is, the carrier recombination region is closer to the area between the second light-emitting sub-layer EML2 and the first adjusting layer ADJ1-1, which is equivalent to a decrease in R1/Y and an increase in R2/Y. Therefore, after the transport balance of carriers changes, the first adjusting layer ADJ1-1 as set can still ensure that the luminescence ratio (R1+R2)/Y of red light to yellow light in the second-emitting unit will not change, thus ensuring that the luminescence color of the device is stable.

In this exemplary embodiment, the electron mobility of the host material in the first adjusting layer ADJ1-1 is greater than the electron mobility of the host material in the first light-emitting sub-layer EML1, ensuring that electrons can migrate normally to the second light-emitting sub-layer EML2 and the first light-emitting sub-layer EML1, and enabling electrons to form the exciton recombination region with holes between the first light-emitting sub-layer EML1 and the second light-emitting sub-layer EML2, thereby ensuring that the first light-emitting sub-layer EML1 can obtain the exciton energy and emit light. The normal migration of electrons may form exciton recombination regions between the second light-emitting sub-layer EML2 and the first light-emitting sub-layer EML1, and between the second light-emitting sub-layer EML2 and the first adjusting layer ADJ1-1, thereby widening the recombination region, and enabling both the first light-emitting sub-layer EML1 and the first adjusting layer ADJ1-1 to obtain the exciton energy and thus emit light.

In this exemplary embodiment, the HOMO energy level of the host material in the first adjusting layer ADJ1-1 is deeper than the HOMO energy level of the host material in the first light-emitting sub-layer EML1, and the HOMO energy level of the host material in the second light-emitting sub-layer EML2. This enables the first adjusting layer ADJ1-1 to block holes transported through the first light-emitting sub-layer EML1, that is, to block all or most of the holes from entering the first adjusting layer ADJ1-1. By blocking the holes as much as possible outside the first adjusting layer ADJ1-1, the exciton recombination region formed by electrons and holes can be made to be located between the first adjusting layer ADJ1-1 and the second light-emitting sub-layer EML2, rather than forming the exciton recombination region in the first adjusting layer ADJ1-1. This setting is conducive to further controlling the stability of the R-Y luminescence ratio.

Specifically, because the luminescence energy of the first adjusting layer ADJ1-1 is lower than the luminescence energy of the second light-emitting sub-layer EML2, when the exciton recombination region is formed in the first adjusting layer ADJ1-1, the low luminescence energy of the first adjusting layer ADJ1-1 will cause an increase in the luminescence proportion of the first adjusting layer ADJ1-1 and a decrease in the luminescence proportion of the second light-emitting sub-layer EML2, resulting in an unstable luminescence ratio R2-Y between the first adjusting layer ADJ1-1 and the second light-emitting sub-layer EML2. Therefore, by setting the HOMO energy level of the host material in the first adjusting layer ADJ1-1 to have the above characteristic to block holes, the holes are made to mainly form excitons outside the first adjusting layer ADJ1-1 with electrons. Then, by utilizing the characteristic that the energy of the first adjusting layer ADJ1-1 is lower than the energy of the second light-emitting sub-layer EML2, a part of excitons enters the first adjusting layer ADJ1-1 through energy transfer and excite the guest material in the first adjusting layer ADJ1-1 to emit light. This can eliminate the influence of the imbalanced luminescence ratio caused by the formation of the recombination region in the first adjusting layer ADJ1-1, and effectively maintain the stability of the overall luminescence ratio (R1+R2)/Y of red light to yellow light in the second-emitting unit 200.

Furthermore, in this exemplary embodiment, the hole mobility of the host material in the first adjusting layer ADJ1-1 is less than the hole mobility of the host material in the first light-emitting sub-layer EML1. This can further restrict the migration of holes within the first adjusting layer ADJ1-1, which is beneficial for further controlling the holes and electrons to form the exciton recombination region between the second light-emitting sub-layer EML2 and the first adjusting layer ADJ1-1. In this way, as the exciton recombination region is mainly located between the first adjusting layer ADJ1-1 and the second light-emitting sub-layer EML2, the exciton energy obtained by the guest material in the first adjusting layer ADJ1-1 and the exciton energy obtained by the guest material in the second light-emitting sub-layer EML2 can be relatively stable. Therefore, the problem of unstable luminescence color ratio between the first adjusting layer ADJ1-1 and the second light-emitting sub-layer EML2 due to the excessive luminescence color of the first adjusting layer ADJ1-1 will not be caused.

From the above analysis, it can be seen that in this exemplary embodiment, by setting the first adjusting layer ADJ1-1 at the side of the second light-emitting sub-layer EML2 away from the first light-emitting sub-layer EML1, the luminescence color of the first adjusting layer ADJ1-1 is the same as the luminescence color of the first light-emitting sub-layer EML1, that is, there are light-emitting layers emitting the same color at two sides of the second light-emitting sub-layer EML2. Because the first adjusting layer ADJ1-1 widens the exciton recombination region, both the first light-emitting sub-layer EML1 and the first adjusting layer ADJ1-1 are enabled to obtain the exciton energy and emit light. Therefore, even if the carrier balance is disrupted due to the change in the transport rate of carriers, the overall luminescence ratio R-Y of red light to yellow light in the second light-emitting unit 200 can be guaranteed to be stable under the action of the first adjusting layer ADJ1-1 as set. This solves the problem of the presence of deviation in the luminescence color of the stacked OLED device at different using stages.

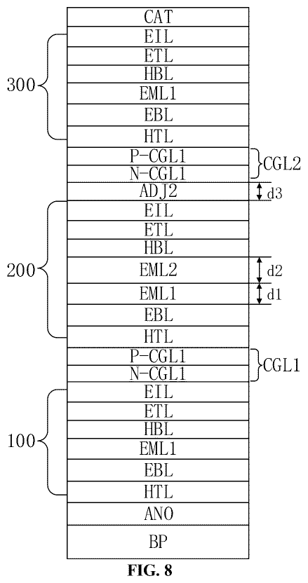

FIG. 7 is a schematic structural diagram of a second light-emitting unit according to another embodiment of the present disclosure. As shown in FIG. 7, in an exemplary embodiment, the first function adjusting layer ADJ1 includes a second adjusting layer IL, and the second adjusting layer IL is a non-light-emitting layer and is located between the first light-emitting sub-layer EML1 and the second light-emitting sub-layer EML2. Therefore, the hole transport layer HTL, the electron blocking layer EBL, the first light-emitting sub-layer EML1, the second adjusting layer IL, the second light-emitting sub-layer EML2, the hole blocking layer HBL, the electron transport layer ETL, and the electron injection layer EIL are sequentially stacked at a side of the first charge generating layer CGL1.

In some embodiments, the second adjusting layer IL is a non-light-emitting layer, and is mainly configured to separate the first light-emitting sub-layer EML1 and the second light-emitting sub-layer EML2, thereby separating the recombination region originally formed between the first light-emitting sub-layer EML1 and the second light-emitting sub-layer EML2 into two recombination regions. In this way, under the drive of different voltages, the proportion of excitons formed by the recombination of holes and electrons in the first light-emitting sub-layer EML1 and the proportion of excitons formed by the recombination of holes and electrons in the second light-emitting sub-layer EML2 will not change with the change of the voltage, thus ensuring that the luminescence color of the device is stable.

Specifically, as described above, the luminescence energy of the first light-emitting sub-layer EML1 is lower than the luminescence energy of the second light-emitting sub-layer EML2. Therefore, under the drive of a low voltage, the first light-emitting sub-layer will light up earlier. As the voltage increases, the ratio of the luminescence brightness of the first light-emitting sub-layer EML1 to the luminescence brightness of the second light-emitting sub-layer EML2 will gradually decrease, resulting in an unstable luminescence color of the stacked OLED device.

In this exemplary embodiment, the second adjusting layer IL separates the recombination region between the first light-emitting sub-layer EML1 and the second light-emitting sub-layer EML2 into two recombination regions. In other words, a part of electrons and holes forms the exciton recombination region in the first light-emitting sub-layer EML1, and a part of electrons and holes forms the exciton recombination region in the second light-emitting sub-layer EML2, which is equivalent to forming a constraint for the exciton energy in each recombination sub-region and avoiding energy rebalancing. As a result, the energy proportion that can be obtained by the first light-emitting sub-layer EML1 and the energy proportion that can be obtained by the second light-emitting sub-layer EML2 at different luminescence brightness are relatively stable. The second adjusting layer IL is equivalent to eliminating the influence of the energy difference between different voltages on the luminescence ratio between the first light-emitting sub-layer EML1 and the second light-emitting sub-layer EML2, thereby ensuring that the luminescence color of the second light-emitting unit 200 is stable.

In this exemplary embodiment, the hole mobility of the second adjusting layer IL is greater than the hole mobility of the host material in the first light-emitting sub-layer EML1, and the hole mobility of the host material in the second light-emitting sub-layer EML2. Therefore, after passing through the first light-emitting sub-layer EML1, holes can migrate in the second adjusting layer IL, and further migrate to the second light-emitting sub-layer EML2, without affecting the recombination of holes and electrons in the second light-emitting sub-layer EML2, thus not affecting the luminescence of the second light-emitting sub-layer EML2.

Furthermore, in this exemplary embodiment, the ratio of the hole mobility of the second adjusting layer IL to the hole mobility of the host material in the second light-emitting sub-layer EML2 may be greater than or equal to 1.5, for example, the ratio may be 1.5, 1.6, 1.7, 1.8, 1.9, 2.0. That is, the hole mobility of the second adjusting layer IL is more than 1.5 times the hole mobility of the host material in the second light-emitting sub-layer EML2, thereby fully ensuring the normal transport of holes.

In this exemplary embodiment, the electron mobility of the second adjusting layer IL may be matched with the electron mobility of the electron transport layer ETL, that is, the electron mobility of the second adjusting layer IL is the same as or close to the electron mobility of the electron transport layer ETL. For example, the ratio of the electron mobility of the second adjusting layer IL to the electron mobility of the electron transport layer ETL may be 0.8 to 1.2. In this way, the second adjusting layer IL will not affect the migration of electrons to the first light-emitting sub-layer EML1, ensuring that electrons can normally pass through the second adjusting layer IL and be transported to the first light-emitting sub-layer EML1 for recombination with holes. Therefore, electrons and holes can recombine in the first light-emitting sub-layer EML1 to provide luminescence energy for the guest material in the first light-emitting sub-layer EML1.

As shown in FIG. 7, in this exemplary embodiment, the thickness do of the second adjusting layer IL as set is less than the thickness d1 of the first light-emitting sub-layer EML1, and the thickness d2 of the second light-emitting sub-layer EML2, respectively, thereby sufficiently reducing the influence on the transport of electrons and/or holes, avoiding the phenomenon that only electrons or holes can be migrated due to the excessive thickness of the second adjusting layer IL, ensuring that both electrons and holes can normally pass through the second adjusting layer IL and form the recombination region with holes and electrons at the corresponding side, and effectively separating the recombination region between the first light-emitting sub-layer EML1 and the second light-emitting sub-layer EML2 into two recombination regions.

Exemplarily, the ratio of the thickness do of the second adjusting layer IL to the thickness dl of the first light-emitting sub-layer EML1 may be 1/15 to 3/5, for example, the ratio may be 1/15, 2/15, 1/5, 4/15, 1/3, 2/5, 7/15, 8/15, 3/5. In some embodiments of the present disclosure, the thickness do of the second adjusting layer IL may be 1 to 3 nm, for example, the thickness do may be 1 nm, 2 nm, 3 nm, and the thickness dl of the first light-emitting sub-layer EML1 may be 5 to 15 nm, for example, the thickness d1 may be 5 nm, 10 nm, 15 nm. In addition, because the luminescence energy of the first light-emitting sub-layer EML1 is lower than the luminescence energy of the second light-emitting sub-layer EML2, the thickness d1 of the first light-emitting sub-layer EML1 is less than the thickness d2 of the second light-emitting sub-layer EML2, thereby avoiding a situation in which excessive deviation is present in the luminescence ratio between the first light-emitting sub-layer EML1 and the second light-emitting sub-layer EML2 due to the first light-emitting sub-layer EML1 obtaining excessive energy. Exemplarily, the thickness d2 of the second light-emitting sub-layer EML2 may be 25 to 40 nm, for example, the thickness d2 may be 25 nm, 30 nm, 35 nm, 40 nm.

It should be understood that the thickness of a certain structure described in the present disclosure can be understood as that the structure has a first surface and a second surface that are opposite to each other along the thickness direction of the driving backplane, and that the distance between the first surface and the second surface in the thickness direction of the driving backplane is the thickness of the structure.

FIG. 8 is a schematic structural diagram of a second light-emitting unit according to yet another embodiment of the present disclosure. As shown in FIG. 8, in an exemplary embodiment, the second light-emitting unit 200 may further include a second function adjusting layer ADJ2, the second function adjusting layer ADJ2 is located between the second light-emitting sub-layer EML2 and the second charge generating layer CGL2, and the second function adjusting layer ADJ2 is configured to block diffusion of the active metal element doped in the second charge generating layer CGL2, i.e., the active metal element doped in the second charge generating layer CGL2 will not diffuse into the first light-emitting sub-layer EML1 and the second light-emitting sub-layer EML2. As a result, the balance of carriers can be maintained, the recombination region can be stable, and thus the device can be controlled to emit light stably. Moreover, because of the locking of the active metal element in the second charge generating layer CGL2, the voltage rise of the device during operation can be reduced, resulting in an increase in the lifetime of the device.

As described above, the second charge generating layer CGL2 is generally formed by an organic material doped with Li element. In this exemplary embodiment, an organic material with a molecular structure having a high binding to the Li atom may be selected to form the second function adjusting layer ADJ2, thereby blocking the diffusion of the Li atom in the second charge generating layer CGL2. For example, an organic material with a molecular steric structure having a small gap may be selected to form the second function adjusting layer ADJ2, thereby enabling the second function adjusting layer ADJ2 to have a good binding to the Li atom.

In this exemplary embodiment, during the use of the device, the carrier recombination region of the second light-emitting unit 200 is widened towards the second light-emitting sub-layer EML2 due to the change in the transport rate of carriers, i.e., the recombination region is widened, which can reduce the average damage to the material structure during the operation of the device, thereby improving the service life of the device.

In this exemplary embodiment, the LUMO energy level of the second function adjusting layer ADJ2 as set is between the LUMO energy level of the electron transport layer ETL and the LUMO energy level of the second charge generating layer CGL2, thereby ensuring that electrons generated by the second charge generating layer CGL2 can normally migrate to the second function adjusting layer ADJ2. In some embodiments of the present disclosure, the LUMO energy level of the second function adjusting layer may be greater than or equal to 3 eV, for example, the LUMO energy level of the second function adjusting layer may be 3 eV, 3.5 eV, 4 eV.

In this exemplary embodiment, the electron mobility of the second function adjusting layer ADJ2 is greater than the electron mobility of the electron transport layer ETL. As a result, the captured electrons can further migrate to the second light-emitting sub-layer EML2 and the first light-emitting sub-layer EML1, which further ensures the normal migration of electrons and ensures that the second light-emitting unit 200 can emit light normally.

As shown in FIG. 8, in an exemplary embodiment, the thickness d3 of the second function adjusting layer ADJ2 is less than the thickness d2 of the second light-emitting sub-layer EML2; and the thickness d3 of the second function adjusting layer ADJ2 may be less than the thickness d1 of the first light-emitting sub-layer EML1, or may be greater than or equal to the thickness d1 of the first light-emitting sub-layer EML1. For example, the ratio of the thickness d3 of the second function adjusting layer ADJ2 to the thickness dl of the first light-emitting sub-layer EML1 may be greater than or equal to 2/3, and less than or equal to 4, for example, the ratio may be 2/3, 1.0, 4/3, 1.5, 2.0, 2.5, 3.0, 3.5, 4.0. At the same time, the ratio of the thickness d3 of the second function adjusting layer ADJ2 to the thickness d2 of the second light-emitting sub-layer EML2 may be greater than or equal to 1/4, and less than or equal to 4/5, for example, the ratio may be 1/4, 2/5, 1/2, 4/5. For example, the thickness of the second function adjusting layer ADJ2 may be 10 to 20 nm, the thickness d1 of the first light-emitting sub-layer EML1 may be 5 to 15 nm, and the thickness d2 of the second light-emitting sub-layer EML2 may be 25 to 40 nm.

In this exemplary embodiment, due to the inherent characteristic of the charge generating layer, during the use of the device, holes provided by the second charge generating layer CGL2 to the third light-emitting unit 300 will slow down, causing the exciton recombination region formed by holes and electrons in the third light-emitting unit to shift towards the second light-emitting unit. The shift of the recombination region will increase the relative density of triplet excitons, and because the third light-emitting layer in the third light-emitting unit 300 is an EML-B organic light-emitting layer, which emits fluorescence, the proportion of triplet excitons undergoing TTA reaction to become singlet excitons will increase, thereby improving the luminescence efficiency of the third light-emitting unit 300.

The present disclosure also provides a display panel, and the display panel may include the stacked OLED device described in any of the above embodiments of the present disclosure.

After considering the specification and practicing the invention disclosed herein, those skilled in the art will easily come up with other implementation solutions of the present disclosure. The purpose of the present disclosure is to cover any variations, uses or adaptations of the present disclosure, and these variations, uses or adaptations follow the general principles of the present disclosure and include common knowledge or commonly used technical means in the technical field that are not disclosed in the present disclosure. The specification and embodiments are only considered exemplary, and the true scope and spirit of the present disclosure are indicated by the accompanying claims.

1. An organic light-emitting diode (OLED) device, comprising a driving backplane and a plurality of sub-pixels distributed in an array on the driving backplane, wherein the sub-pixel comprises:
a first light-emitting unit, located at a side of the driving backplane; and
a second light-emitting unit, located at a side of the first light-emitting unit away from the driving backplane, wherein the second light-emitting unit comprises:
a first light-emitting sub-layer;
a second light-emitting sub-layer, located at a side of the first light-emitting sub-layer away from the driving backplane, wherein the second light-emitting sub-layer is provided with a luminescence color different from a luminescence color of the first light-emitting sub-layer; and
a first function adjusting layer, located between the first light-emitting sub-layer and the second light-emitting sub-layer, or located at a side of the second light-emitting sub-layer away from the first light-emitting sub-layer;
wherein the first function adjusting layer is configured to balance a transport difference of carriers in the second light-emitting unit.

2. The stacked OLED device according to claim 1, wherein the sub-pixel further comprises:
a third light-emitting unit, located at a side of the second light-emitting unit away from the driving backplane, wherein the third light-emitting unit is provided with a same luminescence color as the first light-emitting unit.

3. The OLED device according to claim 1, wherein the first light-emitting sub-layer is provided with less luminescence energy than the second light-emitting sub-layer.

4. The OLED device according to claim 3, wherein the first light-emitting sub-layer is an R light-emitting layer, and the second light-emitting sub-layer is a Y light-emitting layer.

5. The OLED device according to claim 3, wherein the first function adjusting layer comprises a first adjusting layer, the first adjusting layer is located at the side of the second light-emitting sub-layer away from the driving backplane; and
the first adjusting layer is a light-emitting layer, and the first adjusting layer is provided with the same luminescence color as the first light-emitting sub-layer.

6. The OLED device according to claim 5, wherein the second light-emitting unit further comprises:
an electron transport layer, located at the side of the second light-emitting sub-layer away from the first light-emitting sub-layer; wherein
a host material in the first adjusting layer is provided with a greater electron mobility than a host material in the first light-emitting sub-layer.

7. The OLED device according to claim 5, wherein the second light-emitting unit further comprises:
a hole transport layer, located between the first light-emitting sub-layer and the first light-emitting unit; wherein
a host material in the first adjusting layer is provided with a deeper HOMO energy level than a host material in the first light-emitting sub-layer, and a host material in the second light-emitting sub-layer.

8. The OLED device according to claim 7, wherein the host material in the first adjusting layer is provided with a smaller hole mobility than the host material in the first light-emitting sub-layer.

9. The OLED device according to claim 3, wherein the first function adjusting layer comprises a second adjusting layer, the second adjusting layer is a non-light-emitting layer, and the second adjusting layer is located between the first light-emitting sub-layer and the second light-emitting sub-layer.

10. The OLED device according to claim 9, wherein the second light-emitting unit further comprises:
a hole transport layer, located between the first light-emitting sub-layer and the first light-emitting unit; wherein
a hole mobility of the second adjusting layer is greater than a hole mobility of a host material in the first light-emitting sub-layer, and a hole mobility of a host material in the second light-emitting sub-layer.

11. The OLED device according to claim 10, wherein a ratio of the hole mobility of the second adjusting layer to the hole mobility of the host material in the second light-emitting sub-layer is greater than or equal to 1.5.

12. The OLED device according to claim 9, wherein the second light-emitting unit further comprises:
an electron transport layer, located at the side of the second light-emitting sub-layer away from the first light-emitting sub-layer; wherein
an electron mobility of the second adjusting layer is matched with an electron mobility of the electron transport layer.

13. The OLED device according to claim 9, wherein in a thickness direction of the driving backplane, a thickness of the second adjusting layer is less than a thickness of the first light-emitting sub-layer, and a thickness of the second light-emitting sub-layer.

14. The OLED device according to claim 13, wherein a ratio of the thickness of the second adjusting layer to the thickness of the first light-emitting sub-layer is greater than or equal to 1/15, and less than or equal to 3/5; or the thickness of the second adjusting layer is 1 to 3 nm.

15. (canceled)

16. The OLED device according to claim 2, wherein the sub-pixel further comprises:
a first charge generating layer, located between the first light-emitting unit and the second light-emitting unit, wherein the first charge generating layer is configured to provide an electron to the first light-emitting unit and provide a hole to the second light-emitting unit;
a second charge generating layer, located between the second light-emitting unit and the third light-emitting unit, wherein the second charge generating layer is configured to provide an electron to the second light-emitting unit and provided a hole to the third light-emitting unit; and
a second function adjusting layer, located between the second light-emitting sub-layer and the second charge generating layer; wherein
the second charge generating layer is doped with an active metal element, and the second function adjusting layer is configured to block diffusion of the active metal element doped in the second charge generating layer.

17. The OLED device according to claim 16, wherein the second light-emitting unit further comprises:
an electron transport layer, located between the second function adjusting layer and the second charge generating layer; wherein
a LUMO energy level of the second function adjusting layer is between a LUMO energy level of the electron transport layer and a LUMO energy level of the second charge generating layer.

18. The OLED device according to claim 17, wherein the LUMO energy level of the second function adjusting layer is greater than or equal to 3 eV.

19. The OLED device according to claim 16, wherein the second function adjusting layer is provided with a greater electron mobility than the electron transport layer; or
in a thickness direction of the driving backplane, a thickness of the second function adjusting layer is less than or equal to a thickness of the second light-emitting sub-layer.

20. (canceled)

21. The OLED device according to claim 20, wherein a ratio of the thickness of the second function adjusting layer to a thickness of the first light-emitting sub-layer is greater than or equal to 2/3, and less than or equal to 4; and
a ratio of the thickness of the second function adjusting layer to the thickness of the second light-emitting sub-layer is greater than or equal to 1/4, and less than or equal to 4/5.

22. A display panel, comprising the an organic light-emitting diode (OLED) device, wherein the OLED device comprises a driving backplane and a plurality of sub-pixels distributed in an array on the driving backplane, and the sub-pixel comprises:
a first light-emitting unit, located at a side of the driving backplane; and
a second light-emitting unit, located at a side of the first light-emitting unit away from the driving backplane, wherein the second light-emitting unit comprises:
a first light-emitting sub-layer;
a second light-emitting sub-layer, located at a side of the first light-emitting sub-layer away from the driving backplane, wherein the second light-emitting sub-layer is provided with a luminescence color different from a luminescence color of the first light-emitting sub-layer; and
a first function adjusting layer, located between the first light-emitting sub-layer and the second light-emitting sub-layer, or located at a side of the second light-emitting sub-layer away from the first light-emitting sub-layer.
wherein the first function adjusting layer is configured to balance a transport difference of carriers in the second light-emitting unit.
